(19) United States
(12) Patent Application Publication
(10) Pub. No.: US 2018/0019144 A1
(43) Pub. Date: Jan. 18, 2018

(54) VERTICAL WAFER BOAT

(71) Applicant: CoorsTek KK, Tokyo (JP)

(72) Inventor: Takeshi OGITSU, Nishiokitama-gun (JP)

(73) Assignee: CoorsTek KK, Tokyo (JP)

(21) Appl. No.: 15/645,137

(22) Filed: Jul. 10, 2017

(30) Foreign Application Priority Data
Jul. 15, 2016 (JP) 2016-140126

(51) Int. Cl. H01L 21/673; C23C 16/458; H01L 21/02

(52) U.S. Cl. CPC H01L 21/67309; H01L 21/02035; C23C 16/4583; H01L 21/0201

(57) ABSTRACT

A vertical wafer boat includes a plurality of struts formed with a shelf plate portion configured to mount a silicon wafer, and a top plate and a bottom plate which fix upper and lower ends of the struts. The shelf plate portion is inclined downward toward the center of the boat, and a wafer support portion which protrudes upward and abuts on an edge portion of the silicon wafer is formed at a distal end of the shelf plate portion. To obtain the vertical wafer boat which supports a silicon wafer to be processed by a shelf plate portion provided in multiple stages, the vertical wafer boat being capable of reducing a risk of contact between a warped outer peripheral portion of a wafer and the shelf plate portion and suppressing deflection of the silicon wafer even when the silicon wafer has a large diameter.

### BACKGROUND OF THE INVENTION

### Field of the Invention

The present invention relates to a vertical wafer boat, for example, relates to a vertical wafer boat which holds a silicon wafer in a vertical low pressure CVD apparatus used in a manufacturing process of a semiconductor device.

### Description of the Related Art

In the case of depositing film on a surface of a silicon wafer to be processed, a CVD apparatus which performs film deposition by chemical vapor deposition is used. FIG. 3 shows a conventional vertical low-pressure CVD apparatus 30. The CVD apparatus 30 includes a furnace body 31, a process tube 32 which is accommodated in the furnace body 31 and in which a plurality of silicon wafers W are accommodated, and a heater (not illustrated) arranged between the furnace body 31 and the process tube 32. The process tube 32 is formed using high-purity quartz or silicon carbide (SiC) such that an interior temperature is maintained at a high temperature state when the inside of the process tube is heated. Further, the process tube 32 is connected to a vacuum pump (not shown) and the pressure inside the process tube 32 can be reduced to a predetermined pressure (for example, 1.3 kPa) or less.

A boat receiver 34 is provided in a center portion of a base 33 covered by the process tube 32, and a vertical rack-shaped wafer boat 1 is disposed on the boat receiver 34. In the wafer boat 1, a plurality of silicon wafers W are held with a predetermined interval in a vertical direction. A gas introduction pipe 35 configured to introduce a reactive gas into the furnace is disposed in a circumference of the wafer boat 1, and a thermocouple protection pipe 36 with a built-in thermocouple to measure the temperature inside the furnace is provided.

In such a vertical low-pressure CVD apparatus 30, the plurality of silicon wafers W are held in the wafer boat 1, and accommodated in the furnace body 31.

Subsequently, the interior of the furnace is depressurized to a predetermined pressure (for example, 1.3 kPa or less), and is heated to a temperature of, for example, 600 to 900° C., and the reactive gas (a raw material gas) such as SiH₄ together with a carrier gas (such as H2) is introduced into the furnace through the gas introduction pipe 35 such that a polycrystalline silicon film, a silicon nitride film (Si₃N₄), or the like is formed on a surface of the silicon wafer W.

The conventional wafer boat 1 is disclosed in, for example, JP 2008-277781 A. As illustrated in FIG. 4, the wafer boat 1 disclosed in JP 2008-277781 A includes a pair of a top plate 3 and a bottom plate 4 having an outer diameter larger than that of the silicon wafer W to be loaded, and a plurality of (three in FIG. 4) struts 2 which connects the top plate 3 and the bottom plate 4. Incidentally, the top plate 3 and the bottom plate 4 are formed in a disk shape, which is similar to the silicon wafer W.

Further, a plurality of support grooves 2a configured to support the silicon wafer W is provided in the strut 2 as illustrated, partially enlarged, in FIG. 5. As a result, a plurality of shelf plate portions 2b protruding from a side surface of the strut are provided to form multiple stages, and an upper surface of the shelf plate portions is a wafer support portion 2b1. A peripheral edge portion of the silicon wafer W is supported by the wafer support portion 2b1.

However, when the silicon wafer W is supported by the wafer support portion 2b1 which is the upper surface of the shelf plate portion 2b, the wafer support portion 2b1 and a lower surface of the wafer peripheral edge portion are brought into surface-contact with each other. Thus, there is a case where a large number of particles are generated by sliding contact at the time of loading and unloading the wafer and adhere to a back surface of the silicon wafer W.

Further, there is a problem that the particles generated on the back surface of the silicon wafer W at an upper side fall and adhere even to the surface of the silicon wafer W.

Further, when the silicon wafer W is heated during heat treatment, some warp occurs at the wafer peripheral edge portion as illustrated in FIG. 5, an interval (clearance CL) from the upper shelf plate portion 2b decreases so that a wafer edge contacts a lower surface of the shelf plate portion 2b in some cases.

In order to solve the above-described problem, Patent Literature JP H9-82648 A discloses a vertical boat in which the wafer support portion 2b1 of the shelf plate portion 2b formed in the strut 2 is formed as an inclined surface inclined with respect to the horizontal plane as illustrated in FIG. 6.

When the wafer support portion 2b1 is inclined in this manner, the silicon wafer W supported in a substantially horizontal state is supported by line contact. Thus, the generation of particles is suppressed.

Further, when the entire shelf plate portion 2b is inclined as illustrated in FIG. 6, the interval (clearance CL) between the wafer end and the upper shelf plate portion 2b is secured to be large even if some warp occurs at the end of the silicon wafer W during the heat treatment. Thus, the contact between the wafer end and the lower surface of the shelf plate portion 2b can be prevented.

In recent years, however, an increase of a diameter of the silicon wafer W causes it difficult to hold the silicon wafer W in the substantially horizontal state.

That is, a center portion of the silicon wafer W deflects downward by its own weight, and the wafer peripheral edge portion rises upward irrespective of the heat treatment. When the wafer peripheral edge portion rises upward in this manner, the inclined wafer support portion 2b1 and the wafer peripheral edge portion become partially parallel to each other, thereby causing the surface contact to occur instead of the line contact.

Thus, there is a problem that particles are generated due to the sliding contact, stress across the entire silicon wafer W increases, and slip is liable to occur.

### SUMMARY OF THE INVENTION

The present invention has been made under the circumstances as described above, and an object the invention is to provide a vertical wafer boat which supports a silicon wafer to be processed by a shelf plate portion provided in multiple stages, the vertical wafer boat being capable of reducing a risk of contact between a warped outer peripheral portion of a wafer and the shelf plate portion and suppressing deflection of the silicon wafer even when the silicon wafer has a large diameter. The vertical wafer boat according to the present invention includes a plurality of struts having a shelf plate portion as to mount silicon wafers; and a top plate and a bottom plate which fix upper and lower ends of the strut. The shelf plate portion is inclined downward toward the center of the wafer boat, and a wafer support portion, which protrudes upward and abuts on an edge portion of the silicon wafer, is formed at a distal end of the shelf plate portion.

Incidentally, an inclination angle of the shelf plate portion is desirably in a range of 1° or more and 2° or less.

Further, an upper surface of the wafer support portion is desirably formed in a horizontal plane.

Further, it is desirable that a length of the shelf plate portion in a radial direction be in a range of 40 mm or more and 80 mm or less, and a length of the wafer support portion in the radial direction be in a range of 5 mm or more and 10 mm or less.

Since the shelf plate portion is inclined downward toward the center of the boat, according to such a configuration, it is possible to secure a sufficient interval (clearance CL) from the upper shelf plate portion and to prevent contact between the peripheral edge portion of the wafer and a lower surface of the shelf plate portion even when a peripheral edge portion of the wafer is warped upward when the silicon wafer is held for heat treatment.

Further, since the wafer support portion that abuts on the silicon wafer is provided at the distal end of the shelf plate portion, a support position of the silicon wafer is located at a radially inner side of the peripheral edge of the wafer so that it is possible to suppress the amount of deflection to be small even if the center of the silicon wafer having the large diameter is deflected downward by its own weight.

Further, since the wafer support portion is formed in a horizontal plane and the lower surface of the inclined silicon wafer abuts on the wafer support portion by the deflection, line contact is made in the abutment portion, and the stress to the silicon wafer is suppressed to be small, whereby it is possible to prevent occurrence of slip.

### BRIEF DESCRIPTION OF THE DRAWING

FIG. 1 is a partially enlarged cross-sectional view illustrating one of a plurality of struts included in a vertical wafer boat of the present invention;

FIG. 2 is a plan view of a wafer support portion included in one shelf plate portion formed in the strut of FIG. 1;

FIG. 3 is a cross-sectional view of a conventional vertical low pressure CVD apparatus;

FIG. 4 is a perspective view of a conventional wafer boat;

FIG. 5 is a partially-enlarged cross-sectional view of a strut of the conventional wafer boat; and

FIG. 6 is a partially enlarged cross-sectional view of a strut of another conventional wafer boat.

### DESCRIPTION OF THE PREFERRED EMBODIMENTS

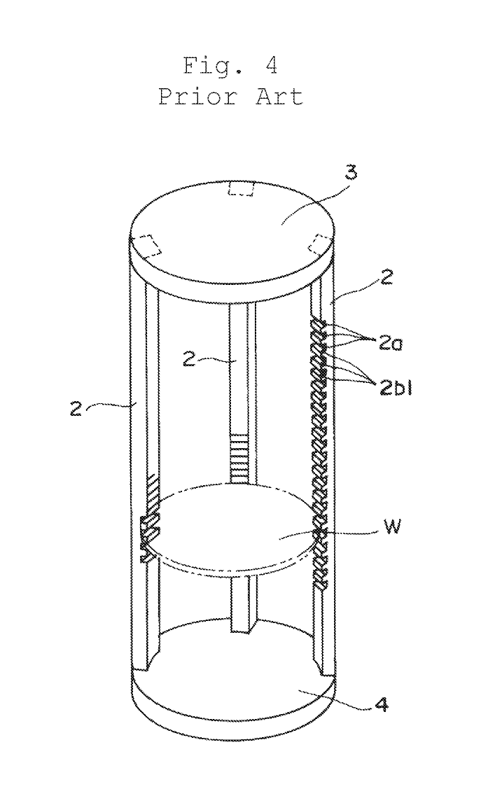

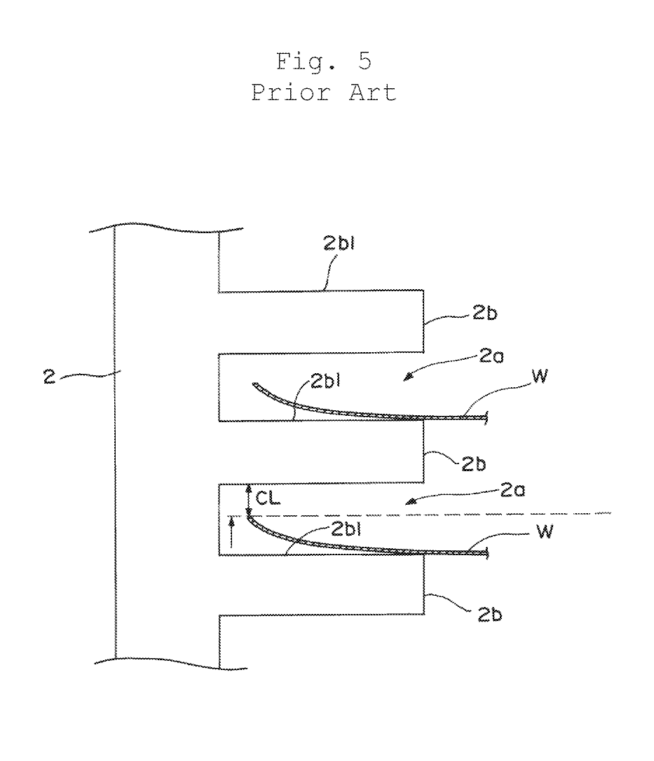

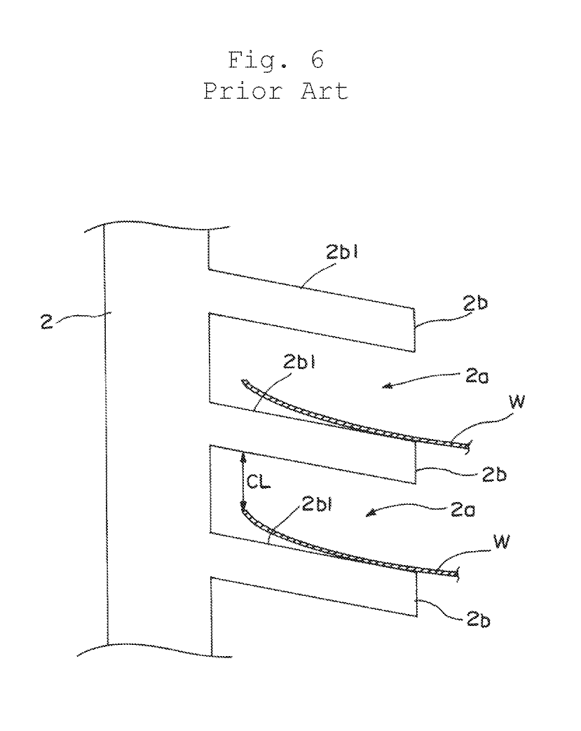

Hereinafter, embodiments of a vertical wafer boat according to the present invention will be described with reference to the drawings. The vertical wafer boat according to the present invention is different from a conventional wafer boat that has been already described with reference to FIGS. 3 and 4 in terms of only a configuration of a shelf plate portion which supports a silicon wafer, and thus, detailed descriptions for the other components will be omitted.

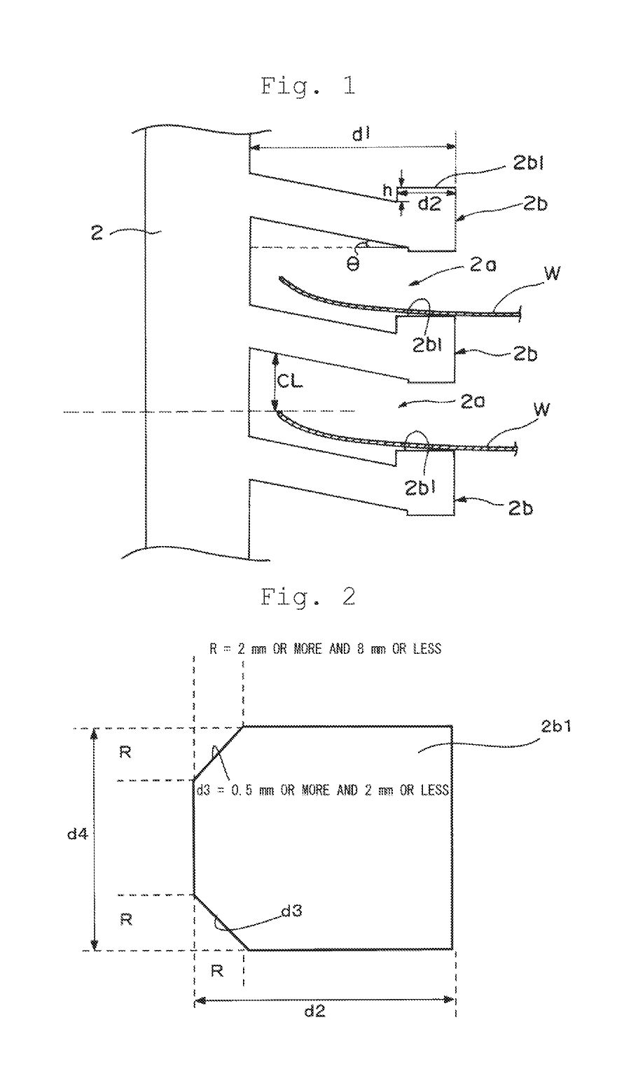

FIG. 1 is a partially enlarged cross-sectional view illustrating one of a plurality of struts of the vertical wafer boat (wafer boat 1) of the present invention.

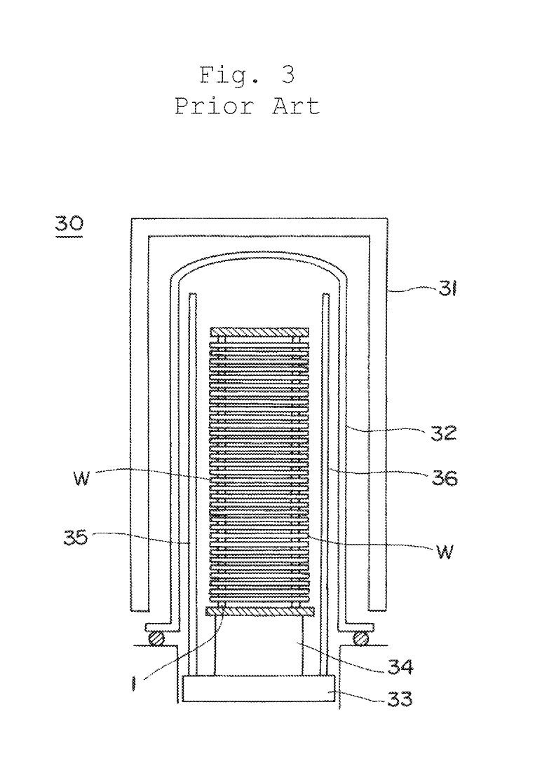

As illustrated in FIG. 1, a plurality of support grooves 2a is formed at an inner side of the strut 2 with a predetermined interval along a longitudinal direction thereof. Further, plate-like shelf plate portions 2b are formed by forming the plurality of support grooves 2a. A wafer support portion 2b1 is formed at a distal end of the shelf plate portion 2b so as to protrude upward by a predetermined height h (preferably, h=0.3 mm or more and 1.0 mm or less), and the wafer support portion 2b1 is formed in a horizontal plane having a predetermined area as illustrated in the plan view in FIG. 2.

A silicon wafer W is held by the boat; that is, a lower surface of a peripheral edge portion of the silicon wafer W abuts on and is supported by the wafer support portion 2b1 of the shelf plate portion 2b formed in each of the plurality of struts 2.

The shelf plate portion 2b is extended in a radial direction in a state in which an upper surface side and a lower surface side thereof are parallel to each other, and is inclined downward toward the center of the wafer boat. An inclination angle θ thereof is preferably 1° or more and 2° or less. This is because there is a risk that the upper surface of the wafer support portion 2b1 and a lower surface of a peripheral edge of the silicon wafer W may be brought into contact with each other at the time of conveying or loading the silicon wafer W when the inclination angle θ exceeds 2°. In contrast, when the inclination angle θ is less than 1°, there is a risk that an upper surface of the peripheral edge portion may be brought into contact with the lower surface of the wafer support portion 2b1 when the silicon wafer W is deformed, that is, when a warp occurs.

Further, a length d1 of the shelf plate portion 2b in the radial direction is formed to be 40 mm or more and 80 mm or less. An optimum value of the length d1 in the radial direction is different depending on a diameter of the silicon wafer W to be supported. For example, when the diameter of the silicon wafer W is 300 mm, the length d1 is preferably 80 mm. By adjusting the length of the shelf plate portion 2b in the radial direction and setting a support position by the wafer support portion 2b1 in this manner, a position of the wafer support portion 2b1 moves to a radially inner side of the wafer from the peripheral edge end of the wafer; as a result, it is possible to reduce the amount of self-weight deflection of the silicon wafer W.

Further, right and left corners at the distal end of the wafer support portion 2b1 of the shelf plate portion 2b are chamfered as illustrated in FIG. 2. Preferably, a chamfering width d3 is 0.5 mm or more and 2 mm or less, and R chamfering of 2 mm or more and 8 mm or less is carried out.

Further, a length d2 of the wafer support portion 2b1 in the radial direction is formed to be 5 mm or more and 10 mm or less. A width d4 in a circumferential direction may be formed to a desired length depending on a shape of the strut 2.

The surface of the wafer support portion 2b1 is preferably roughened to have a surface roughness Ra of 0.2 μm or more and 0.8 μm or less. This roughening treatment prevents occurrence of scratches on a back surface of the wafer and slip, and further the wafer support portion 2b1 from sticking to the silicon wafer W.

With thus configured wafer boat, since the shelf plate portion 2b is inclined downward toward the center of the boat, it is possible to secure a sufficient interval (clearance CL) from the upper shelf plate portion 2b and to prevent contact between the peripheral edge portion of the silicon wafer W and the lower surface of the shelf plate portion 2b even if the peripheral edge portion of the silicon wafer W is warped upward at the time of holding the silicon wafer W for heat treatment.

Further, since the wafer support portion 2b1 abutting on the silicon wafer W is provided at the distal end of the shelf plate portion 2b, the support position of the silicon wafer W is located at the radially inner side of the peripheral edge end of the wafer, and the deflection amount can be reduced even if the center of the silicon wafer W having the large diameter is deflected downward by its own weight.

Further, since the wafer support portion 2b1 is formed in a horizontal plane and the inclined lower surface of the silicon wafer W due to self-weight deflection abuts on the wafer support portion, line contact is made in the abutment portion, and stress to the silicon wafer W is reduced, whereby the occurrence of slip can be prevented.

The vertical wafer boat according to the present invention will be further described on the basis of Examples. In these Examples, the vertical wafer boat illustrated in the above-described embodiment was manufactured, and the performance of the obtained wafer boat was verified.

Specifically, the plurality of support grooves configured to place the silicon wafer was formed on a SiC base material by a rotary cutting tool to form the strut.

Subsequently, an upper surface (engagement surface) of the shelf plate portion formed by the support groove was roughened by sandblasting treatment so as to have Ra of 0.5 μm.

Further, the obtained strut was washed with an acid, then washed out with pure water, and dried to obtain a complete form of the strut. A necessary number of the struts was formed in the same manner, and then, the top plate and the bottom plate were assembled to these struts, thereby manufacturing the assembly-type vertical wafer boat.

In addition, fifty silicon wafers having a diameter of 300 mm were loaded in the manufactured vertical wafer boat, and heat-treated in a furnace at 750° C. for one hour.

In Examples 1 to 8, verification was performed regarding a preferable length of the shelf plate portion in the radial direction and length of the wafer support portion in the radial direction by observing the number of particles adhering to the surface of the silicon wafer after the heat treatment (the number of particles of 0.2 μm or more that adhere on the surface of the silicon wafer of 300 mm in diameter) and a slip occurrence state of the back surface of the silicon wafer.

Table 1 shows conditions of Examples 1 to 8 and verified results thereof. In the verified results shown in Table 1, “Good” of “the number of adhering particles” indicates a state in which adhesion of particles of 0.2 μm or more was not observed on the surface of the silicon wafer of 300 mm in diameter, “Fair” indicates a state in which adhesion of a small amount (twenty or less of particles of 0.2 μm or more on the surface of the silicon wafer of 300 mm in diameter) of particles was confirmed, and “Poor” represents a result in which adherence of a lot (more than 20 and 50 or less of particles of 0.2 μm or more on the surface of the silicon wafer of 300 mm in diameter) of particles was confirmed. Further, “Good” in the “slip occurrence state” indicates a state in which no slip occurs, and “Poor” indicates a state in which slip has occurred.

TABLE 1

| | Ex- | Ex- | Ex- | Ex- | Ex- | Ex- | Ex- | Ex- |
|---|---|---|---|---|---|---|---|---|
| | ample | ample | ample | ample | ample | ample | ample | ample |
| | 1 | 2 | 3 | 4 | 5 | 6 | 7 | 8 |
| Length of shelf plate | 39 mm | 40 mm | 80 mm | 81 mm | 60 mm | | | |
| portion in radial direction | | | | | | | | |
| Length of wafer support | 7 mm | | | | 4 mm | 5 mm | 10 mm | 11 mm |
| portion in radial direction | | | | | | | | |
| Inclination angle of shelf | 1.5° | | | | | | | |
| plate portion | | | | | | | | |
| Step height of wafer | 0.6 mm | | | | | | | |
| support portion | | | | | | | | |
| Surface roughness (Ra) | 0.5 μm | | | | | | | |
| of wafer support portion | | | | | | | | |
| Number of adhering | Fair | Good | Good | Fair | Fair | Good | Good | Fair |
| particles | | | | | | | | |
| Slip generation state | Good | Good | Good | Good | Good | Good | Good | Good |

As shown in Table 1, particularly when the length of the shelf plate portion in the radial direction was 40 mm or more and 80 mm or less (the length of the wafer support portion in the radial direction was fixed at 7 mm), particles did not adhere, and good results were obtained as the results of Examples 1 to 4.

Further, particularly when the length of the wafer support portion in the radial direction was 5 mm or more and 10 mm or less (the length of the shelf plate portion in the radial direction was fixed at 60 mm), no particles adhered, and good results were obtained as the results of Examples 5 to 8.

In Examples 9 to 12, verification was carried out regarding a preferable inclination angle of the shelf plate portion by observing the number of particles adhering to the surface of the silicon wafer after the heat treatment and the state of slip occurrence.

Table 2 shows conditions of the inclination angle of the shelf plate portion and verification results thereof. In the verification results shown in Table 2, “Good” of “the number of adhering particles” indicates a state in which adhesion of particles of 0.2 μm or more was not observed on the surface of the silicon wafer of 300 mm in diameter, “Fair” indicates a state in which adhesion of a small amount (twenty or less of particles of 0.2 μm or more on the surface of the silicon wafer of 300 mm in diameter) of particles was detected, and “Poor” represents a result in which adherence of a lot (more than 20 and 50 or less of particles of 0.2 μm or more on the surface of the silicon wafer of 300 mm in diameter) of particles was detected. Further, “Good” in the “slip occurrence state” indicates a state in which no slip occurs, and “Poor” indicates a state in which slip has occurred.

Table 2 shows results of Comparative Examples that were carried out subsequent to Examples. In Comparative Example 1, the shelf plate portion is inclined, but the wafer support portion protruding upward is not provided. In Comparative Example 2, the shelf plate portion is not inclined but horizontal, and has the wafer support portion protruding upward at the distal end. In Comparative Example 3, the shelf plate portion is not inclined but horizontal, and has no wafer support portion protruding upward at the distal end.

TABLE 2

| | | | | Compar- | Compar- | Compar- |
|---|---|---|---|---|---|---|
| Ex- | Ex- | Ex- | Ex- | ative | ative | ative |
| ample | ample | ample | ample | Example | Example | Example |
| 9 | 10 | 11 | 12 | 1 | 2 | 3 |

| | | | | |
|---|---|---|---|---|
| Length of shelf plate | 60 mm | 30 mm | 60 mm | |
| portion in radial direction | | | | |
| Length of wafer support | 7 mm | None | 20 mm | None |
| portion in radial direction | | | | |

| | | | | | | |
|---|---|---|---|---|---|---|
| Inclination angle of shelf | 0.9° | 1.0° | 2.0° | 2.1° | 1.5° | 0° |

| plate portion | | | | | | | |
|---|---|---|---|---|---|---|---|
| Step height of wafer | 0.6 mm | | | | None | 0.6 mm | None |
| support portion | | | | | | | |
| Surface roughness (Ra) | 0.5 μm | | | | | | |
| of wafer support portion | | | | | | | |
| Number of adhering | Fair | Good | Good | Fair | Poor | Poor | Poor |
| particles | | | | | | | |
| Slip generation state | Good | Good | Good | Good | Poor | Good | Poor |

As results of Examples 9 to 12, particularly when the inclination angle of the shelf plate portion was 1.0° or more and 2.0° or less, no particles adhered and good results were obtained as shown in Table 2.

Further, the deflection was large since the diameter of the silicon wafer was large, the surface contact with the shelf plate portion was made so that a lot of particles adhered, and the slip occurred in Comparative Example 1 (the shelf plate portion was inclined and the support portion was not protruded). In Comparative Example 2 (the shelf plate portion was horizontal and the protruding support part was provided), no slip occurred, but a large number of particles adhered. In Comparative Example 3 (the shelf plate portion was horizontal and the support portion was not protruded), a large number of particles adhered, and the slip occurred.

As a result of the above-described examples according to the configuration of the present invention, it has been confirmed that generation of particles and occurrence of slip can be prevented by reducing the risk of contact between the shelf plate and the warp of the outer peripheral portion of the silicon wafer while minimizing deflection of the silicon wafer.

### REFERENCE SIGNS LIST (FOR TAIWAN)

1 Wafer boat
2 Strut
2a Support groove
2b Shelf plate portion
2b1 Wafer support portion
3 Top plate
4 Bottom plate
W Silicon wafer

What is claimed is:

1. A vertical wafer boat comprising:
a plurality of struts formed with a shelf plate portion being configured to mount a silicon wafer; and
a top plate and a bottom plate which fix upper and lower ends of the struts,
wherein the shelf plate portion is inclined downward toward the center of the boat, and a wafer support portion which protrudes upward and abuts on an edge portion of the silicon wafer is formed at a distal end of the shelf plate portion.

2. The vertical wafer boat according to claim 1, wherein an inclination angle of the shelf plate portion is in a range of 1° or more and 2° or less.

3. The vertical wafer boat according to claim 1, wherein an upper surface of the wafer support portion is formed in a horizontal plane.

4. The vertical wafer boat according to claim 1, wherein a length of the shelf plate portion in a radial direction is in a range of 40 mm or more and 80 mm or less.

5. The vertical wafer boat according to claim 1, wherein a length of the wafer support portion in a radial direction is in a range of 5 mm or more and 10 mm or less.
